(19) United States
(12) Patent Application Publication
(10) Pub. No.: US 2024/0389302 A1
(43) Pub. Date: Nov. 21, 2024

(54) CONTACT FOOT WET PULLBACK WITH LINER WET PUNCH

(71) Applicant: Micron Technology, Inc., Boise, ID (US)

(72) Inventors: Jerome A. Imonigie, Boise, ID (US); Chia Ying Lin, Taichung (TW); Davide Dorigo, Taichung (TW); Elisabeth Barr, Boise, ID (US); Wan Rou Luo, Taichung (TW); Shi Han Wang, Taichung (TW); Sanjeev Sapra, Boise, ID (US); Ashwin Panday, Boise, ID (US); Vivek Yadav, Boise, ID (US)

(21) Appl. No.: 18/658,787

(22) Filed: May 8, 2024

Related U.S. Application Data
(60) Provisional application No. 63/467,836, filed on May 19, 2023.

(51) Int. Cl. H10B 12/00

(52) U.S. Cl. CPC H10B 12/315; H10B 12/033; H10B 12/482

(57) ABSTRACT

Methods, systems, and devices for contact foot wet pullback with liner wet punch are described. A first etching operation may be performed on a stack of materials and a first insulative material to form a plurality of segments including contacts, the contacts formed from a first conductive material of the stack of materials and extending at least partially through the first insulative material. A first liner material may be deposited over the segments and the first insulative material, and a directional gas bias operation may be performed to transform a portion of the first liner material in contact with an extension of the contacts into a second liner material. A second etching operation may be performed to remove the second liner material and expose a surface of the extension, and a third etching operation may be performed remove at least a portion of the extension.

### CROSS REFERENCE

The present application for patent claims priority to U.S. Patent Application No. 63/467,836 by Imonigie et al., entitled “CONTACT FOOT WET PULLBACK WITH LINER WET PUNCH,” filed May 19, 2023, which is assigned to the assignee hereof, and which is expressly incorporated by reference herein.

### TECHNICAL FIELD

The following relates to one or more systems for memory, including contact foot wet pullback with liner wet punch.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports contact foot wet pullback with liner wet punch in accordance with examples as disclosed herein.

FIG. 2 shows an example of a memory die that supports contact foot wet pullback with liner wet punch in accordance with examples as disclosed herein.

FIG. 3 shows an example of a process diagram that supports contact foot wet pullback with liner wet punch in accordance with examples as disclosed herein.

FIG. 4 shows an example of a process diagram that supports contact foot wet pullback with liner wet punch in accordance with examples as disclosed herein.

FIG. 5 shows an example of a process diagram that supports contact foot wet pullback with liner wet punch in accordance with examples as disclosed herein.

FIG. 6 shows an example of a process diagram that supports contact foot wet pullback with liner wet punch in accordance with examples as disclosed herein.

FIG. 7 shows an example of a process diagram that supports contact foot wet pullback with liner wet punch in accordance with examples as disclosed herein.

FIG. 8 shows an example of a process diagram that supports contact foot wet pullback with liner wet punch in accordance with examples as disclosed herein.

FIG. 9 shows an example of a process diagram that supports contact foot wet pullback with liner wet punch in accordance with examples as disclosed herein.

FIG. 10 shows a block diagram of a manufacturing system that supports contact foot wet pullback with liner wet punch in accordance with examples as disclosed herein.

FIG. 11 shows a flowchart illustrating a method or methods that support contact foot wet pullback with liner wet punch in accordance with examples as disclosed herein.

### DETAILED DESCRIPTION

A process for fabricating memory devices may include one or more etching and depositing steps to form one or more elements of the memory devices. For example, a formation process of one or more memory cells may include depositing one or more conductive materials and insulative materials over a substrate and performing an etching procedure to form one or more segments of stacked materials. In some examples, each segment may include a digit line and an insulative cap, and one or more contacts may be used to couple the digit line with one or more first active regions of the substrate. In some cases, the formation process may include performing a dry etch operation on the stacked materials and an insulative material above the substrate and stopping the dry etch operation to avoid damaging one or more second active regions of the substrate. However, stopping the dry etch operation before the second active regions may result in the formation of a lateral extension (e.g., foot) of one or more contacts, which may increase susceptibility to shorts with nearby conductors. In some examples, an additional etch operation may be performed to remove the extensions, but may thin out portions of the contacts above or below the extensions (e.g., may cause necking) while also affecting the insulative material, the second active regions, and other materials of the segments.

To mitigate shorts and remove an extension of one or more contacts while minimally affecting the insulative material and other materials of the segments, a formation process may include selective removal of one or more of the lateral extensions by performing a contact foot wet pullback with a liner punch. For example, after forming the one or more segments using a first etching operation, a metal hard mask (MHM) used in the first etching operation may be removed using a cleaning operation, and a liner material (e.g., a thin liner material), such as an oxide material, may then be deposited over the segments. The liner material may be punched (e.g., selective etched) by applying a directional gas bias operation to transform portions of the liner material into a second liner material and performing a second etching operation to remove the transformed portions of the liner material. A third etching operation (e.g., single dispense or cyclic etch) may then be applied to remove at least a portion of the extensions exposed due to the punching operation (e.g., wet foot pullback). Following the third etching operation, another liner material may be deposited over the liner material or in place of the liner material after stripping off the liner material. In some examples, the contact foot wet pullback operation described herein may result in a removal of the extension without causing substantial necking, which may result in less errors in manufacturing as well as increased performance due to a reduction in shorts.

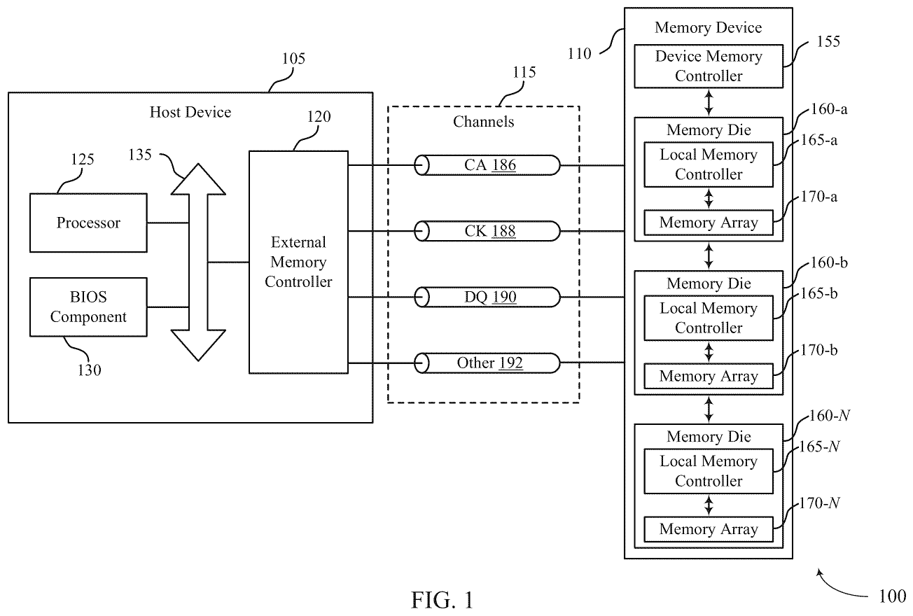

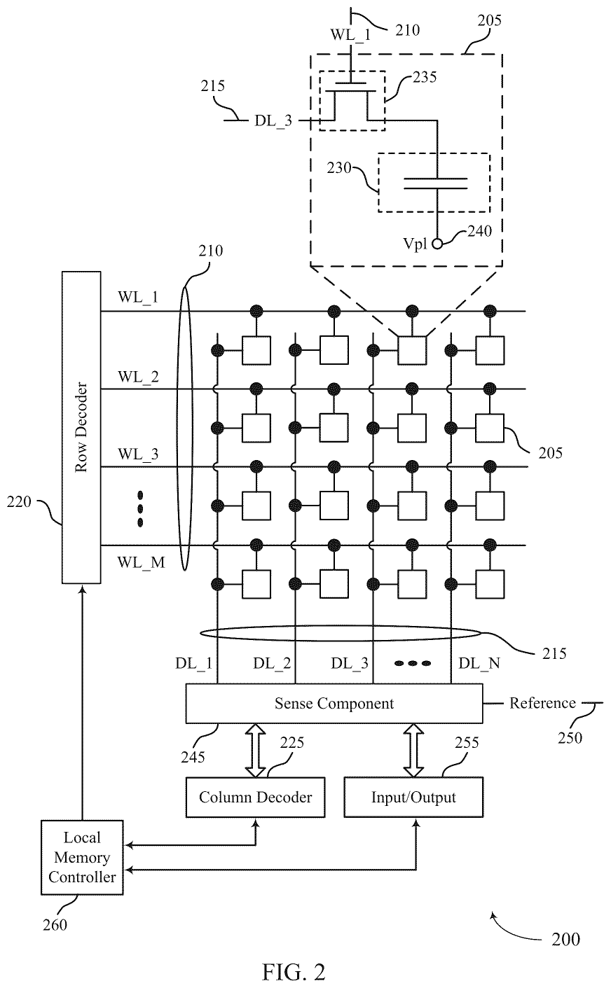

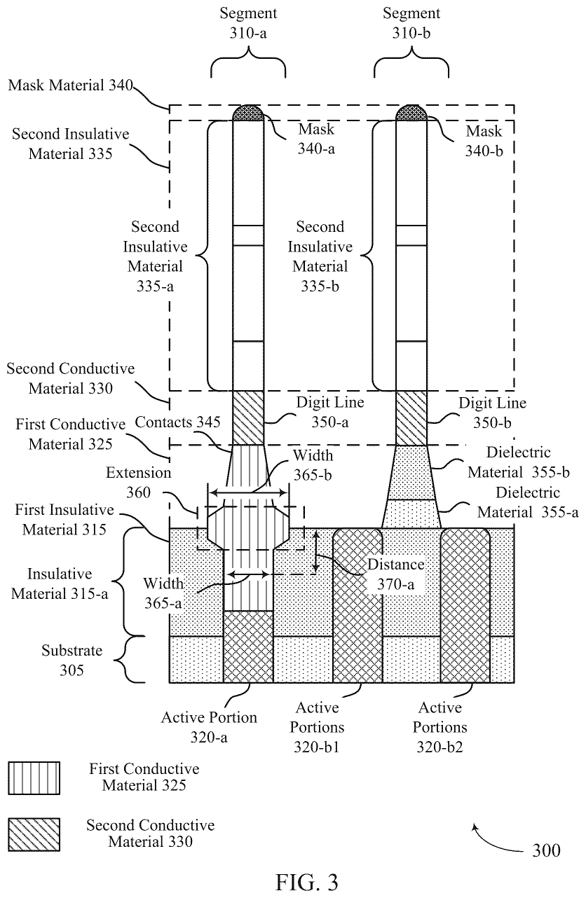

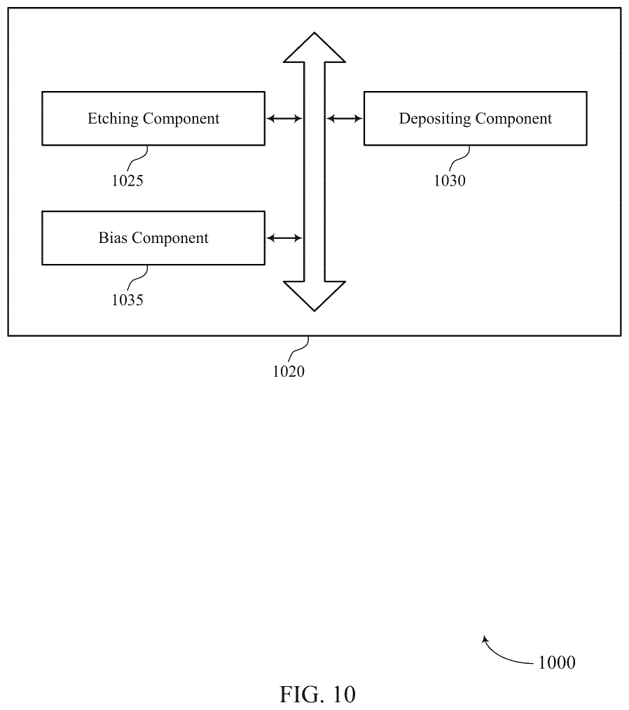

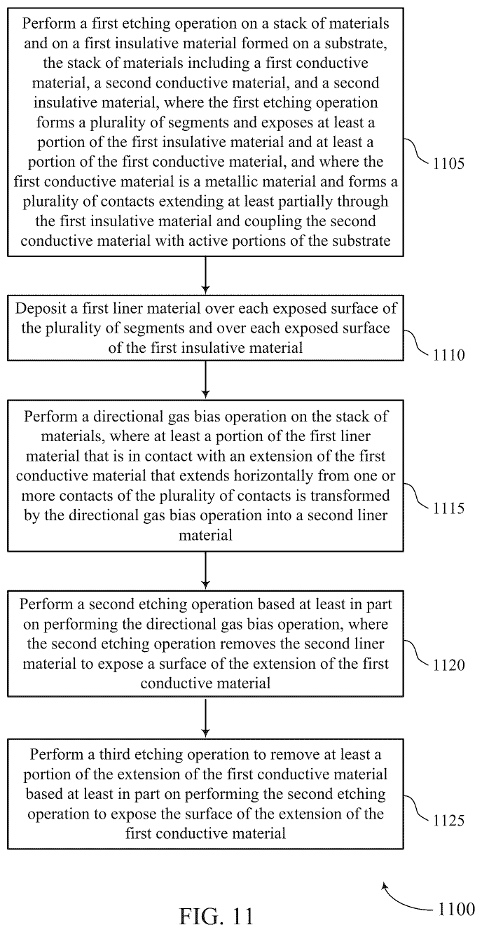

Features of the disclosure are initially described in the context of systems and dies as described with reference to FIGS. 1 and 2. Features of the disclosure are described in the context of process diagrams with reference to FIGS. 3 through 9. These and other features of the disclosure are further illustrated by and described with reference to an apparatus diagram and flowcharts that relate to contact foot wet pullback with liner wet punch as described with reference to FIGS. 10 and 11.

FIG. 1 shows an example of a system 100 that supports contact foot wet pullback with liner wet punch in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

In some examples, to mitigate shorts and remove an extension of one or more contacts coupling one or more digit lines (e.g., bit lines) with one or more active regions of a substrate (e.g., coupled with one or more transistors associated with one or more memory cells of a memory array 170 of a memory die 160), a formation process may include selective removal of one or more contact extensions using a contact foot wet pullback with a liner punch. For example, after forming one or more segments of stacked materials using a first etching operation, an MHM used in the first etching operation may be removed using a cleaning operation, and a liner material, such as a carbon doped oxide material, may then be deposited over the segments. The liner material may be punched (e.g., selective etched) by applying a directional gas bias operation to transform portions of the liner material into a second liner material and performing a second etching operation to remove the transformed portions of the liner material. A third etching operation may then be applied to remove at least a portion of the extensions exposed due to the punching operation (e.g., a wet foot pullback may be performed). Following the third etching operation, another liner material may be deposited over the liner material or in place of the liner material after stripping off the liner material.

In addition to applicability in memory systems as described herein, techniques for contact foot wet pullback with liner wet punch may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by reducing necking in one or more contacts of memory device structures for memory cells (e.g., memory cells of a memory die 160) while reducing a width of one or more extensions (e.g., feet) or the one or more contacts, which may reduce a quantity of errors in access operations and increase a reliability of memory cells, among other benefits. Additionally, or alternatively, the described techniques may reduce one or more dimensions of each memory cell (e.g., by reducing a width of the one or more extensions), thereby reducing cell pitch and enabling higher density of memory cells, which may lead to increased performance due to smaller memory cells and thus faster memory access.

FIG. 2 shows an example of a memory die 200 that supports contact foot wet pullback with liner wet punch in accordance with examples as disclosed herein. The memory die 200 may be an example of the memory dies 160 described with reference to FIG. 1. In some examples, the memory die 200 may be referred to as a memory chip, a memory device, or an electronic memory apparatus. The memory die 200 may include one or more memory cells 205 that may be programmable to store different logic states (e.g., programmed to one of a set of two or more possible states). For example, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). In some examples, the memory cells 205 may be arranged in an array, such as a memory array 170 described with reference to FIG. 1.

In some examples, a memory cell 205 may store a charge representative of the programmable states in a capacitor. DRAM architectures may include a capacitor that includes a dielectric material to store a charge representative of the programmable state. In other memory architectures, other storage devices and components are possible. For example, nonlinear dielectric materials may be employed. The memory cell 205 may include a logic storage component, such as capacitor 230, and a switching component 235 (e.g., a cell selection component). The capacitor 230 may be an example of a dielectric capacitor or a ferroelectric capacitor. A node of the capacitor 230 may be coupled with a voltage source 240, which may be the cell plate reference voltage, such as Vpl, or may be ground, such as Vss.

The memory die 200 may include access lines (e.g., word lines 210, digit lines 215) arranged in a pattern, such as a grid-like pattern. An access line may be a conductive line coupled with a memory cell 205 and may be used to perform access operations on the memory cell 205. In some examples, word lines 210 may be referred to as row lines. In some examples, digit lines 215 may be referred to as column lines or bit lines. References to access lines, row lines, column lines, word lines, digit lines, or bit lines, or their analogues, are interchangeable without loss of understanding. Memory cells 205 may be positioned at intersections of the word lines 210 and the digit lines 215.

Operations such as reading and writing may be performed on the memory cells 205 by activating access lines such as a word line 210 or a digit line 215. By biasing a word line 210 and a digit line 215 (e.g., applying a voltage to the word line 210 or the digit line 215), a single memory cell 205 may be accessed at their intersection. The intersection of a word line 210 and a digit line 215 in a two-dimensional or in a three-dimensional configuration may be referred to as an address of a memory cell 205. Activating a word line 210 or a digit line 215 may include applying a voltage to the respective line.

Accessing the memory cells 205 may be controlled through a row decoder 220, or a column decoder 225, or any combination thereof. For example, a row decoder 220 may receive a row address from the local memory controller 260 and activate a word line 210 based on the received row address. A column decoder 225 may receive a column address from the local memory controller 260 and may activate a digit line 215 based on the received column address.

Selecting or deselecting the memory cell 205 may be accomplished by activating or deactivating the switching component 235 using a word line 210. The capacitor 230 may be coupled with the digit line 215 using the switching component 235. For example, the capacitor 230 may be isolated from digit line 215 when the switching component 235 is deactivated, and the capacitor 230 may be coupled with digit line 215 when the switching component 235 is activated.

A word line 210 may be a conductive line in electronic communication with a memory cell 205 that is used to perform access operations on the memory cell 205. In some architectures, the word line 210 may be coupled with a gate of a switching component 235 of a memory cell 205 and may be operable to control the switching component 235 of the memory cell. In some architectures, the word line 210 may be coupled with a node of the capacitor of the memory cell 205 and the memory cell 205 may not include a switching component.

A digit line 215 may be a conductive line that couples the memory cell 205 with a sense component 245. In some architectures, the memory cell 205 may be selectively coupled with the digit line 215 during portions of an access operation. For example, the word line 210 and the switching component 235 of the memory cell 205 may be operable to couple or isolate the capacitor 230 of the memory cell 205 and the digit line 215. In some architectures, the memory cell 205 may be coupled with the digit line 215.

The sense component 245 may be operable to detect a state (e.g., a charge) stored on the capacitor 230 of the memory cell 205 and determine a logic state of the memory cell 205 based on the stored state. The sense component 245 may include one or more sense amplifiers to amplify or otherwise convert a signal resulting from accessing the memory cell 205. The sense component 245 may compare a signal detected from the memory cell 205 to a reference 250 (e.g., a reference voltage). The detected logic state of the memory cell 205 may be provided as an output of the sense component 245 (e.g., to an input/output 255), and may indicate the detected logic state to another component of a memory device (e.g., a memory device 110) that includes the memory die 200.

The local memory controller 260 may control the accessing of memory cells 205 through the various components (e.g., row decoder 220, column decoder 225, sense component 245). The local memory controller 260 may be an example of the local memory controller 165 described with reference to FIG. 1. In some examples, one or more of the row decoder 220, column decoder 225, and sense component 245 may be co-located with the local memory controller 260. The local memory controller 260 may be operable to receive one or more of commands or data from one or more different memory controllers (e.g., an external memory controller 120 associated with a host device 105, another controller associated with the memory die 200), translate the commands or the data (or both) into information that can be used by the memory die 200, perform one or more operations on the memory die 200, and communicate data from the memory die 200 to a host (e.g., a host device 105) based on performing the one or more operations. The local memory controller 260 may generate row signals and column address signals to activate the target word line 210 and the target digit line 215. The local memory controller 260 also may generate and control various signals (e.g., voltages, currents) used during the operation of the memory die 200. In general, the amplitude, the shape, or the duration of an applied voltage or current discussed herein may be varied and may be different for the various operations discussed in operating the memory die 200.

The local memory controller 260 may be operable to perform one or more access operations on one or more memory cells 205 of the memory die 200. Examples of access operations may include a write operation, a read operation, a refresh operation, a precharge operation, or an activate operation, among others. In some examples, access operations may be performed by or otherwise coordinated by the local memory controller 260 in response to various access commands (e.g., from a host device 105). The local memory controller 260 may be operable to perform other access operations not listed here or other operations related to the operating of the memory die 200 that are not directly related to accessing the memory cells 205.

In some examples, to mitigate shorts and remove an extension of one or more contacts coupling one or more digit lines 215 with one or more active regions of a substrate (e.g., coupled with one or more transistors associated with one or more memory cells 205), a formation process may include selective removal of one or more contact extensions using a contact foot wet pullback with a liner punch. For example, after forming one or more segments of stacked materials using a first etching operation, an MHM used in the first etching operation may be removed using a cleaning operation, and a liner material, such as an oxide material, may then be deposited over the segments. The liner material may be punched (e.g., selective etched) by applying a directional gas bias operation to transform portions of the liner material into a second liner material and performing a second etching operation to remove the transformed portions of the liner material. A third etching operation may then be applied to remove at least a portion of the extensions exposed due to the punching operation (e.g., a wet foot pullback may be performed). Following the third etching operation, another liner material may be deposited over the liner material or in place of the liner material after stripping off the liner material.

FIG. 3 shows an example of a process diagram 300 that supports contact foot wet pullback with liner wet punch in accordance with examples as disclosed herein. The process diagram 300 may illustrate a portion of a memory device, such as a memory device 110 or the memory die 200. For example, the process diagram 300 may illustrate a first set of processing steps for forming one or more memory cells (e.g., memory cells 205) on top of a substrate 305 as described with reference to FIGS. 1 and 2. In some examples, the process diagram 300 may illustrate a first step before a contact foot wet pullback operation with liner wet punch for forming a set of segments 310 to support forming the memory cells. In some examples, the segments 310 may be part of a DRAM device.

In some examples, during prior manufacturing operations, one or more materials may be formed on the substrate 305. For example, a first insulative material 315 (e.g., an insulative layer) may be deposited over the substrate 305 and one or more active portions 320 of the substrate, and a first conductive material 325 may be formed to extend at least partially through the first insulative material. For example, one or more preliminary etching operations may be performed to create a pattern of cavities extending in a first horizontal direction extending out of the page in the first insulative material 315, and the first conductive material 325 may be deposited within the cavities to form multiple spaced portions of the first conductive material 325 extending in the first horizontal direction to form a set of contacts 345 using a first etching operation described below. The first conductive material 325 may additionally be deposited over the multiple portions and the first insulative material 315 to reach an upper edge of the first conductive material 325 as shown in FIG. 3. A second conductive material 330 may also be formed over the first conductive material, following by a second insulative material 335, and a mask material 340. In some examples, the mask material 340 may be etched to form one or more mask materials 340 extending in the first horizontal direction, including mask materials 340-a and 340-b. The mask materials 340-a and 340-b may be MHMs, and may function as stop layers in one or more etching operations. The first conductive material 325, the second conductive material 330, and the second insulative material 335 may represent a stack of materials for forming the one or more segments 310. One or more additional insulative materials (for example, a third insulative material) may be formed on the substrate 305 in between the first conductive material 325 deposited in the one or more cavities. For example, additional cavities may be formed in the first conductive material 325 deposited above the first insulative material 315 and between the deposited multiple portions of the first conductive material 325 in the first horizontal direction, and the one or more additional insulative materials may be deposited within the additional cavities to form multiple dielectric materials 355 (e.g., 355-a and 355-b between a second set of contacts, as well as additional dielectric materials 355 between the set of contacts 345). Additionally, or alternatively, the first insulative material 315 may be deposited to extend to the upper edge of the first conductive material 325 before depositing the first conductive material 325, may etched to form the dielectric materials 355-a and 355-b extending in the first horizontal direction (e.g., made of a same material as the first insulative material 315-a), and the first conductive material 325 may be deposited over and between the dielectric materials 355 to form the first conductive material 325 extending to the upper edge of the first conductive material 325. In some examples, the stack of materials, the first insulative material 315, and the substrate 305 may extend within a horizontal plane.

In some examples, a first etching operation may be performed on the stack of materials and on the first insulative material 315 formed on the substrate 305. For example, the first etching operation may be performed to etch through the stack of materials to form a plurality of segments 310 extending in the first horizontal direction including a segment 310-a and a segment 310-b (e.g., a second segment). The first etching operation may form the segment 310-a and the segment 310-b by etching vertically where the mask materials 340-a and 340-b, which may each extend in the first horizontal direction, are not present. The first etching operation may thus form the first insulative material 315-a from at least a portion of the first insulative material 315, and may form the segment 310-a from at least a portion of the first conductive material 325, a portion of the second conductive material 330, and a portion of the second insulative material 335 extending in a first horizontal direction into and/or out of the page with respect to FIG. 3. In some examples, the first insulative material 315-a may include all of the first insulative material 315 after the deposition of the first conductive material 325 (e.g., may not be etched in the first etching operation), or may include at least a portion of the first insulative material 315 (e.g., the first insulative material 315, extending to the upper edge of the first conductive material 325 or slightly above the upper edge of the first insulative material 315-a, may be etched to reveal a surface of one or more active portions 320).

The first segment 310-a may include a set of contacts 345 (e.g., one or more contacts) extending (e.g., aligned) in the first horizontal direction. The set of contacts 345 may include multiple contacts spaced according to the multiple portions of the first conductive material extending through the first insulative material 315. Thus, the set of contacts 345 may extend at least partially through the first insulative material 315-a to couple a digit line 350-a (or another access line) to one or more first active portions 320-a of the substrate 305. For example, the one or more active portions 320-a may be part of one or more transistors within the substrate 305, where the set of contacts 345 may couple the digit line 350-a with the transistors. In some examples, the first conductive material 325 (and thus the set of contacts 345) may be a metallic material, such as a metal nitride material (e.g., titanium nitride (TiN)). The first segment 310-a may include a digit line 350-a formed from the at least the portion of the second conductive material 330, where the second conductive material may be a metallic conductor material (e.g., Tungsten (W) or another metal). The first segment 310-a may additionally include a second insulative material 335-a formed from the second insulative material 335, which may form a cap for the segment 310-a, and may be a nitride material (e.g., silicon nitride (SiN)). In some examples, the first etching operation may expose at least a portion of the first insulative material 315 and at least a portion of the first conductive material 325. For example, the first etching operation may expose a surface of the set of contacts 345, as well as an upper edge of the first insulative material 315-a.

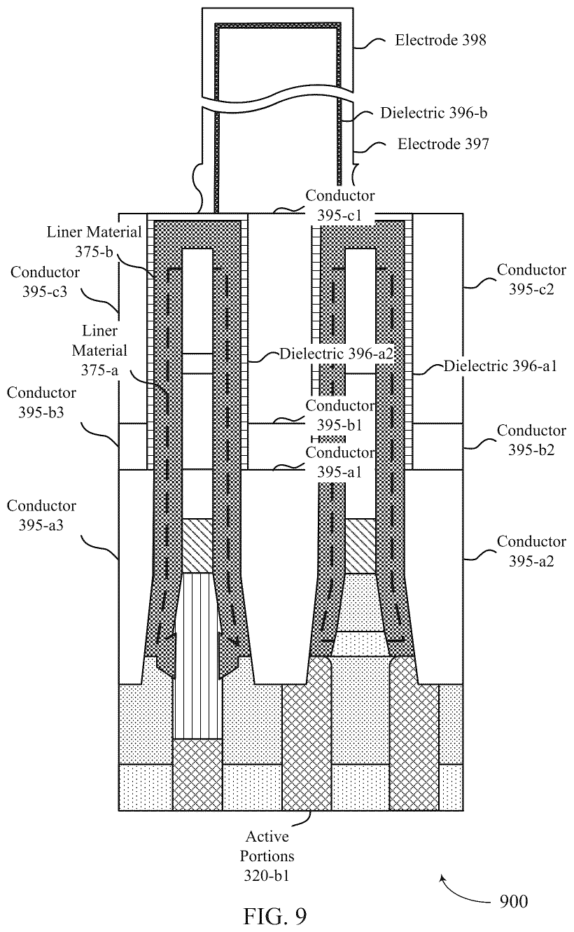

In some examples, the first etching operation may also form the second segment 310-b. For example, the second segment 310-b may include a third insulative material in contact with at least a portion of the first insulative material 315-a, at least a portion of the second conductive material 330 (e.g., a fourth conductive material different from a third conductive material described with respect to FIG. 9) forming a digit line 350-b, and at least a portion of the second insulative material 335 forming a second insulative material 335-b (e.g., a fourth insulative material, or cap for the segment 310-b). In some examples, the third insulative material may be made of two or more different materials. For example, the third insulative material may include the dielectric material 355-a and the dielectric material 355-b, where the third insulative material is in contact with at least a portion of the first insulative material 315-a via dielectric material 355-a. The dielectric materials 355 may extend in the first horizontal direction, or may include one or more interspersed dielectric materials 355 distributed along the first horizontal direction (e.g., between a second set of contacts within the second segment 310-b as described herein). In some examples, at least the portion of the first insulative material 315-a may be between different second active portions 320-b of the substrate 305 (e.g., between one or more second active portions 320-b1 and one or more second active portions 320-b2).

In some examples, the dielectric material 355-a may be a first inter-layer dielectric material (ILD) and the dielectric material 355-b may be a second ILD material. In some examples, the first insulative material 315-a, the second insulative materials 335-a and 335-b, the dielectric material 355-a, the dielectric material 355-b, or any combination thereof, may be examples of ILD oxide materials, examples of ILD nitride materials, or any combination thereof (e.g., SiOC, SiO₂, Si₃N₄, or other oxides and nitrides). For example, an ILD material of the dielectric material 355-b may be different from the ILD material of the dielectric material 355-a, and both the first ILD material and the second ILD material may be different from a third ILD material of the first insulative material 315-a. By way of another example, the first ILD material, the second ILD material, and the third ILD material may be a same material (e.g., if the first insulative material 315 is etched to form the dielectric materials 355 as described herein).

In some examples, the etching operation may form one or more extensions of the first conductive material 325, where one or more contacts of the set of contacts 345 may each include an extension 360. For example, the first etching operation (e.g., dry etch) may be a relatively non-aggressive operation to avoid damaging one or more second active portions 320-b (e.g., active area silicon (Si)). Thus, the first etching operation may be stopped based on one or more second active portions 320-b of the substrate 305 to avoid damaging the second active portions 320-b. Stopping the first etching operation may thus leave a portion of the one or more contacts at least partially unetched, resulting in the formation of a “foot” extending from each of the one or more contacts. However, the one or more contacts (e.g., TiN) may be close enough to one or more features that the presence of the extensions 360 may cause shorts between the contacts and other features of the memory structure. For example, the contact may short to other contacts (e.g., doped polycrystalline Silicon (Poly Si) contacts) used to connect a memory access device to a capacitor for the memory cell. This may result in one or more read or write errors during access operations, among other disadvantages. In some examples, the first etching operation may at least partially etch the first insulative material 315-a and the second active portions 320-b due to a composition of the first etching operation material or due to the first etching operation being more aggressive for etching TiN of the first conductive material 325 to form the set of contacts 345. For example, while a doped polycrystalline Silicon (Poly-Si) contact may be formed using a more aggressive etching operation to completely remove the extensions 360 while minimally affecting the second active portions 320-b (and/or the first insulative material 315-a) due to a different composition of an etch material, a TiN contact (e.g., the set of contacts 345) may include the extensions 360 using a less aggressive etching operation to avoid affecting the second active portions 320-b as described herein.

To illustrate the extensions 360, each contact of the set of contacts 345 may include a first dimension, such as a width 365-a, orthogonal to the first horizontal direction and to a vertical direction. In some examples, the width 365-a may represent a nominal width of the contacts, or a nominal critical dimension (CD), where a CD may be a smallest feature of the set of contacts 345 and may define a cell pitch of one or more memory cells. For example, the nominal width, or the width 365-a, may be defined at a vertical location defined by a distance 370-a, where the distance 370-a may extend from an upper edge of the first insulative material 315-a to halfway between the upper edge of the first insulative material 315-a and a bottom edge of the set of contacts 345. Additionally, each contact may have a second dimension, such as a width 365-b, orthogonal to the first horizontal direction and to the vertical direction at a second vertical location aligned with the upper edge of the first insulative material 315-a. In some examples, the second width 365-b may be greater than 20 percent larger than the width 365-a, for example, due to the formation of the extensions 360 during the first etching operation. For example, the width 365-a may be less than or equal to 10 nm, whereas second width 365-b of the extensions 360 (e.g., TiN feet) may be greater than, or substantially greater than, 10 nm wide (e.g., 16 nm wide). In some cases, an upper edge of the one or more second active portions 320-b may also be at the second vertical location of the upper edge of the first insulative material 315-a and the second dimension of the set of contacts 345.

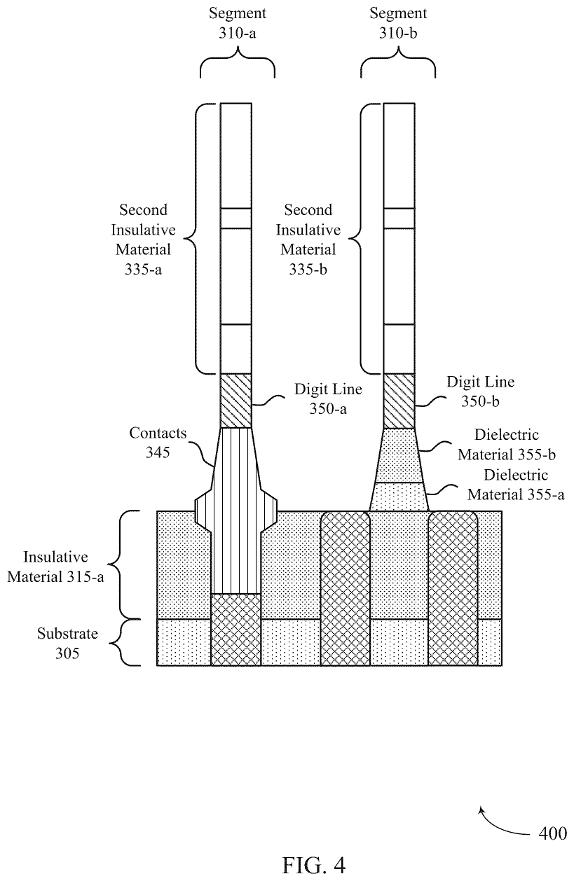

In some examples, the extensions 360 may be etched to remove at least a portion of the extensions 360. However, although the width 365-b may be reduced, the etching may reduce the width 365-a (e.g., nominal width) at other portions of one or more contacts of the set of contacts 345, which may result in widths much less than 10 nm. For example, such etching may cause “necking,” or thin contact widths smaller than defined a percentage or range of percentages of a CD (e.g., less than 10%, 20%, 30%, 40%, 50%, 60%, and/or 70% of a CD). Additionally, or alternatively, the etching may impact the digit lines 350, the second insulative materials 335 (e.g., caps), the second active portions 320-b, and the first insulative material 315-a. Thus, improved methods may be desired to etch the extensions 360 (e.g., TiN foot) selectively without causing necking and without impacting the digit lines 350 and second insulative materials 335. In some examples, the operations described with respect to FIGS. 4-8 may represent an example of a selective etching operation for etching the extensions 360 of the one or more contacts of the contacts 345 (e.g., TiN). For example, FIGS. 4-8 may demonstrate a contact foot wet pullback operation that allows selective wet etch of a TiN foot to achieve a nominal contact width (or diameter) of less than or equal to 10 nm.

FIG. 4 shows an example of a process diagram 400 that supports contact foot wet pullback with liner wet punch in accordance with examples as disclosed herein. For example, the process diagram 400 may illustrate the segments 310-a and 310-b described with reference to FIG. 3 following a first step of a contact foot wet pullback operation, described with respect to FIG. 3. In some examples, the process diagram 400 may illustrate the segments 310 following a cleaning operation to remove the mask materials 340-a and 340-b. For example, the mask materials 340-a and 340-b described with respect to FIG. 3 may be removed according to a cleaning operation. The cleaning operation may represent a dry etching operation, a wet etch operation as described herein with respect to FIGS. 1-3, or another type of removal or cleaning procedure. For example, the cleaning operation may involve a hydrofluoric (HF) acid solution wet etch.

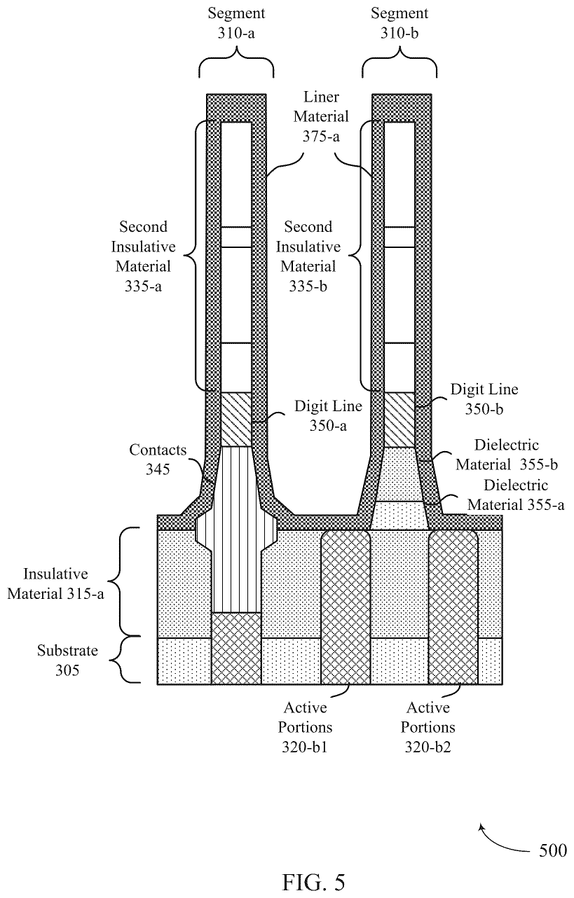

The cleaning operation may be an example of a selective etching operation to remove the mask materials 340-a and 340-b while leaving at least a majority of the second insulative materials 335, the digit lines 350, the contacts 345, the first insulative material 315-a, and the dielectric materials 355 unetched. In some examples, an upper surface of the second insulative materials 335-a and 335-b may be exposed based on removing the mask materials 340-a and 340-b using the cleaning operation. Additionally, or alternatively, the first etching operation of FIG. 3 and the cleaning operation of FIG. 4 may result in trimming or stripping at least some portions the second insulative materials 335 (e.g., caps), the digit lines 350, the contacts 345, the first insulative material 315-a, and the dielectric materials 355 in preparation of the procedures described with respect to FIGS. 5-9.

FIG. 5 shows an example of a process diagram 500 that supports contact foot wet pullback with liner wet punch in accordance with examples as disclosed herein. For example, the process diagram 500 may illustrate the segments 310-a and 310-b described with reference to FIGS. 3 and 4 following a second step of a contact foot wet pullback operation (e.g., after the first etching operation and cleaning process of FIGS. 3 and 4). In some examples, the process diagram 500 may illustrate the segments 310 following a deposition of a first liner material (e.g., a thin low-k value dielectric oxide material, such as a carbon doped silicon oxide, or SiOC) over the segments 310 and the first insulative material 315.

For example, a first liner material 375-a may be deposited to cover at least a portion of a surface of the contacts 345, the digit lines 350, and/or the second insulative materials 335 of the segments 310 of stacked materials. For example, the liner material may be deposited over each exposed surface of the segments 310-a and 310-b, including each exposed surface of the second insulative materials 335, the digit lines 350, the contacts 345, the dielectric materials 355. Additionally, or alternatively, the first liner material 375-a may be deposited to cover at least a portion of a surface of the upper edge of the first insulative material 315-a and at least a portion of a surface of the upper edge of the one or more second active portions 320-b. For example, the liner material 375-a may additionally be deposited over each exposed surface of the first insulative material 315 and the second active portions 320-b of the substrate 305. In some examples, the liner material 375-a may be a low-k dielectric, such as a carbon doped silicon oxide (SiOC).

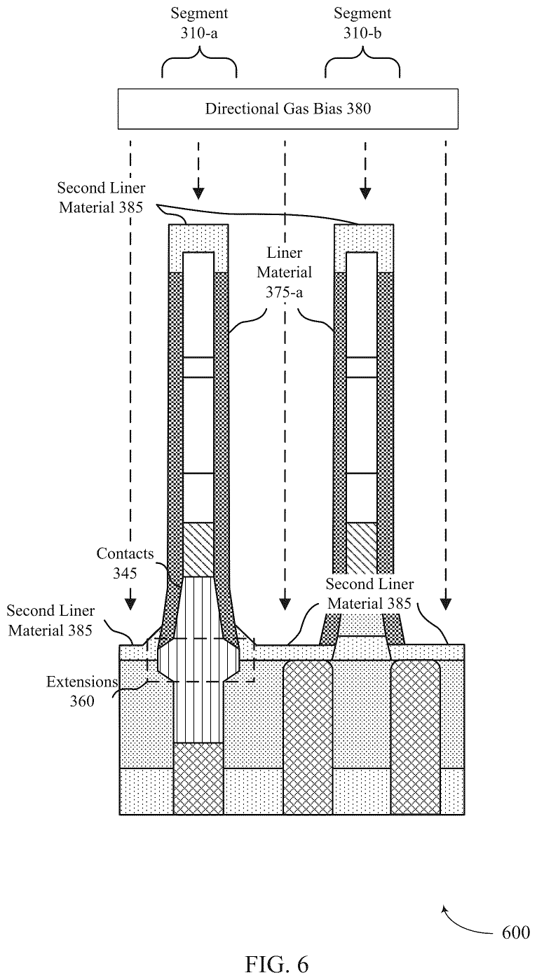

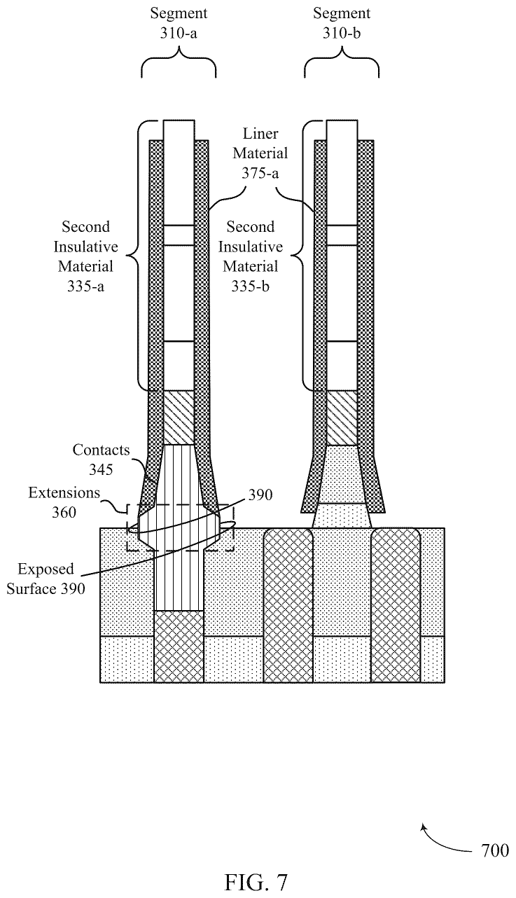

FIG. 6 shows an example of a process diagram 600 that supports contact foot wet pullback with liner wet punch in accordance with examples as disclosed herein. For example, the process diagram 600 may illustrate the segments 310-a and 310-b described with reference to FIGS. 3-5 following a third step of a contact foot wet pullback operation. In some examples, the process diagram 600 may illustrate the segments 310 following performance of a directional gas bias operation (e.g., after the liner deposition of FIG. 5). In some examples, FIG. 6 and FIG. 7 may represent one or more operations performed as part of a liner (e.g., oxide liner) wet punch operation.

For example, a directional gas bias operation 380 may be performed. For example, an oxygen gas plasma (e.g., O₂) may be applied to the first liner material 375-a. In some examples, the directional gas bias operation 380 may transform one or more portions of the first liner material 375-a into a second liner material 375-b by removing one or more elements from the one or more portions of the first liner material 375-a. For example, an O₂ gas plasma applied to the first liner material 375-a may remove a quantity of carbon (C) from the SiOC of one or more portions of the first liner material 375-a, transforming the first liner material 375-a of the one or more portions into a silicon dioxide (SiO₂), or the second liner material 385. In some examples, removing the carbon from one or more portions of the first liner material 375-a may prepare the one or more portions for a second etching operation. For example, the first liner material 375-a may be resistant to a specific etching operation (e.g., a wet etching operation), whereas the second liner material 385 may be easily etched using the second etching operation as described with respect to FIG. 7. That is, removing the carbon may result in the one or more portions being susceptible to the second etching operation.

In some examples, the directional gas bias operation 380 may affect the portions of the first liner material 375-a illustrated in FIG. 6 due to the directionality of the directional gas bias operation 380. For example, the directional gas bias operation 380 may be applied in a vertical direction to keep the liner material 375-a on the sides of the segments 310. Thus, at least a portion of the first liner material 375-a that is in contact with one or more extensions 360 that extend horizontally from one or more contacts of the contacts 345 may be transformed by the directional gas bias operation 380 into the second liner material 385. Additionally, or alternatively, one or more portions of the first liner material 375-a at the top of the segments 310 may be transformed into the second liner material 385. By way of another example, the first liner material 375-a may be transformed by one or more additive processes. For example, the first liner material 375-a may be doped with a material so that the second liner material 375-b has a different etching sensitivity and may be etched accordingly (e.g., doped portions may be removed more easily). For example, the first liner material 375-a may be SiO₂, where the second liner material 375-b may be doped with Carbon to form SiOC.

FIG. 7 shows an example of a process diagram 700 that supports contact foot wet pullback with liner wet punch in accordance with examples as disclosed herein. For example, the process diagram 700 may illustrate the segments 310-a and 310-b described with reference to FIGS. 3-6 following a fourth step of a contact foot wet pullback operation. In some examples, the process diagram 700 may illustrate the segments 310 following a second etching operation to remove the second liner material 385.

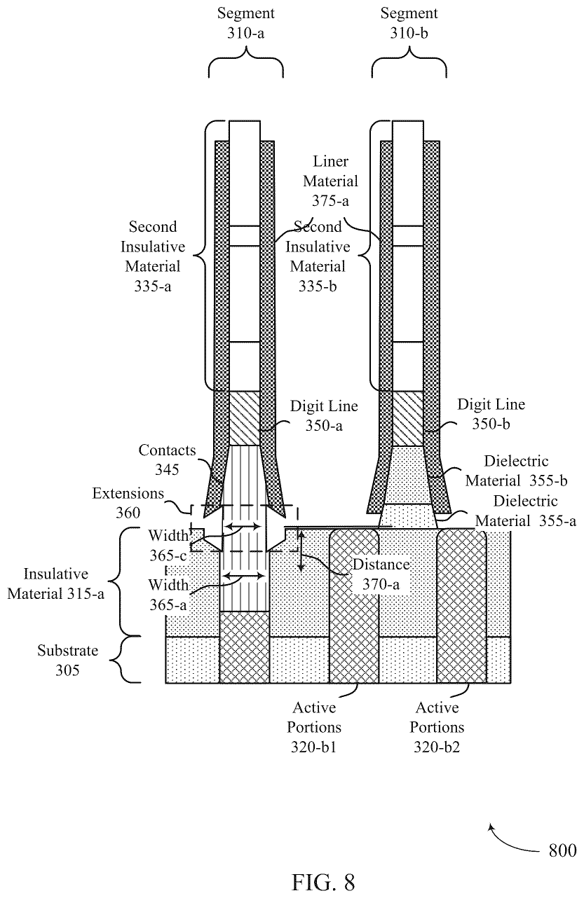

For example, a second etching operation may be performed based on the directional gas bias operation 380 described with respect to FIG. 6. The second etching operation may remove the second liner material 385 to expose a surface of the extensions 360 of one or more contacts of the contacts 345. For example, the second etching operation may remove SiO₂ around the extensions 360 to expose surfaces 390 of one or more extensions 360 for a third etching operation described with respect to FIG. 8. In some examples, the second liner material 385 may be removed by using a selective etching operation that may etch the second liner material 385 but not etch the first liner material 375-a. For example, the etching operation may include a HF wet etch (for example, a buffered HF solution), which may remove the SiO₂ while leaving SiOC portions covering the second insulative materials 335, the digit lines 350 and at least one or more portions of the set of contacts 345, such as portions above the extensions 360. Thus, the operations of FIGS. 7 and 8 may punch (e.g., selectively etch) the first liner material 375-a with a combination of O₂ directional strip and HF solution to open the bottom of the features of the segments 310 (e.g., remove SiO₂) and expose one or more TiN feet from the bottom of the segments 310.

FIG. 8 shows an example of a process diagram 800 that supports contact foot wet pullback with liner wet punch in accordance with examples as disclosed herein. For example, the process diagram 800 may illustrate the segments 310-a and 310-b described with reference to FIGS. 3-7 following a fifth step of a contact foot wet pullback operation. In some examples, the process diagram 800 may illustrate the segments 310 following a third etching operation to remove at least a portion of the extensions 360.

For example, a third etching operation may be performed to remove at least a portion of the extensions 360 extending from one or more contacts of the set of contacts 345 based on exposing the surfaces 390 of the extensions 360 of the one or more contacts using the second etching operation described with respect to FIG. 7. For example, the third etching operation may be an example of a wet etch, such as a high temperature (e.g., between 100° C. and 200° C.) sulfuric acid (H₂SO₄) solution etch. In some examples, the third etching operation may be a single dispense etching operation, for example, including a single application of the H₂SO₄ solution. Additionally, or alternatively, the third etching operation may be a cyclic etching operation including one or more applications of the H₂SO₄ solution (e.g., at a lower concentration or for a smaller amount of time compared to a single dispense operation to achieve a more uniform etch of the extensions 360). For example, a cyclic third etching operation may involve multiple applications (e.g., between 5 and 30 seconds) of H₂SO₄ solution followed by rinse after each application, where a single dispense third etching operation may include a single run (e.g., between 30 and 300 seconds) followed by a rinse.

In some examples, the third etching operation may selectively etch the extensions 360 (e.g., TiN) while minimally affecting the rest of the contacts 345 (e.g., contact material above the foot), the digit lines 350, and the second insulative materials 335. For example, the remaining first liner material 375-a may cover the rest of the contacts 345 (e.g., TiN), the digit lines 350 (e.g., W), and the second insulative materials 335 (e.g., SiN), thereby protecting the rest of the segments 310 during the third etching operation, and reducing necking and other unintended impact of the third etching operation. In some examples, the H₂SO₄ etch may minimally impact the second active portions 320-b (e.g., Si) and the first insulative material 315-a (e.g., SiO₂ or SiN) due to a composition of the second active portions 320-b and the first insulative material 315-a. In some examples, the H₂SO₄ etch may thus be referred to as a Selective TIN Layer Etching (STLE) operation.

In some examples, the steps of the selective etching operation (described with respect to FIGS. 3-8) may reduce a width of one or more contacts of the contacts 345. For example, the original width 365-b of the extensions 360 of the one or more contacts may be reduced to a width 365-c smaller than the width 365-b at the vertical location of the upper edge of the first insulative material 315-a. The width 365-c may represent a new second dimension of the contacts 345, and may be less than or equal to 20 percent (or another percentage) larger than the width 365-a (e.g., than the first dimension, or than a nominal contact width or contact diameter). Additionally, or alternatively, the width 365-c may be greater than or equal to 20 percent smaller than the width 365-a. Thus, the contacts 345 may have a generally uniform width, which may reduce an amount of shorts between one or more contacts of the contacts 345 and one or more elements (e.g., may reduce an amount of TiN to Poly-Si shorts). In some examples, the operations described herein may achieve an extent of the contact foot being within a threshold (e.g., 20%) of a target contact width (e.g., width 365-c), where the target contact with is less than or equal to 10 nm, irrespective of variability due to stopping the first etching operation due to the protective first liner material 375-a and punch operation described herein. In some examples, a resolution of one or more manufacturing devices may change (e.g., achieve a desired CD resolution, such as a 10 nm resolution). In such an example, the nominal contact width may be, for example 10 nm or less than 10 nm, and the width 365-c may be within 20% of the nominal contact width while avoiding shorts due to the contact foot wet pullback operation described herein.

In some examples, the operations described herein may be performed within any memory system. For example, the described processes may be performed in a NAND system, such as a 3D NAND architecture, among other memory architectures to reduce a width of extensions 360. Additionally, or alternatively, the describe processes may be performed with respect to any vertical structure to remove an extension (e.g., foot) that may occur at a boundary of the vertical structure and other materials. For example, a vertical structure (e.g., a segment 310) may be formed using a stack of a variety of materials (e.g., in place of or including one or more of the digit lines 350, second insulative material 335, and the like) including a material with one or more extensions 360. A dimension of the extensions 360 (e.g., horizontal width) of the vertical structures may be reduced using the selective etching operation (e.g., including a wet pullback with a liner punch) described with respect to FIGS. 3-8, or using a similar procedure (e.g., with different liner materials and/or etching operations).

FIG. 9 shows an example of a process diagram 900 that supports contact foot wet pullback with liner wet punch in accordance with examples as disclosed herein. For example, the process diagram 500 may illustrate the segments 310-a and 310-b described with reference to FIGS. 3-8 following one or more second processing steps for a formation of one or more memory cells. In some examples, the process diagram 900 may illustrate the segments 310 following a formation of different materials and one or more memory cells following the contact foot wet pullback operation described with respect to FIGS. 3-8. In some cases, FIG. 9 may represent a structure that may be repeated.

For example, after the third etching operation, a third liner material 375-b may be deposited over the segments 310. In some examples, the third liner material 375-b may be deposited to replace the first liner material 375-a. For example, a fourth etching operation may be performed to remove (e.g., strip off) the first liner material 375-a remaining after the third etching operation and to expose at least a portion of one or more contacts of the set of contacts 345 and the second insulative materials (or caps) 335 (and Dielectric materials 355). The third liner material 375-b (e.g., a pristine or new liner material) may be deposited to cover at least a portion of the contacts 345, the digit lines 350, the second insulative materials 335 (and/or the dielectric materials 355), the upper edge of the first insulative material 315-a, the upper edge of the active portions 320 (e.g., 320-b1 and 320-b2), or any combination thereof. For example, the third liner material 375-b may be deposited over each exposed surface of the segments 310 and over each exposed surface of the first insulative material 315-a. In some examples, the third liner material 375-b may be a same liner material as the first liner material 375-a (e.g., may be a carbon doped silicon oxide material, such as SiOC).

By way of another example, the first liner material 375-a may be left in place and the third liner material 375-b may be deposited over remaining portions of the first liner material following the operations described in FIGS. 3-8. For example, the third liner material 375-a may be deposited over each exposed surface of the first insulative material 315-a (e.g., low-k dielectric) that were exposed as a result of the second etching operation described with respect to FIG. 7, and may be deposited over the exposed portions of the one or more contacts of the set of contacts 345 after the third etching operation. In some examples, an amount or thickness of the third liner material 375-b deposited over the first liner material 375-a may be dependent on the remaining first liner material 375-a, and may be deposited to achieve or give a desired thickness equivalent to a baseline thickness (e.g., a thickness of the third liner material 375-b deposited if removing the first liner material 375-a).

In some examples, various conductive materials may be deposited between the segments 310. For example, conductors 395-a (e.g., Poly-Si) may be deposited between the segment 310-a and the segment 310-b (e.g., conductor 395-a1) and between the segments 310 and other segments 310 (e.g., conductors 395-a2 and 395-a3) after depositing the third liner material 375-b. For example, the conductor 395-a2 may be formed above the first insulative material 315-a and in contact with at least a second active portion 320-b of the second active portions 320-b of the substrate 305, where at least a portion of the third liner material 375-b is between the conductor 395-a2 and the segments 310-a and 310-b. In some examples, one or more conductors may be deposited between the segments 310. For example, conductors 395-a (395-a1-395-a3) may be deposited after an additional etching operation so that the conductors 395-a extend at least partially into the first insulative material 315-a to couple with active portions 320-b, where the active portions 320-b may be partially etched during the additional etching operation. A dielectric material, such as a dielectric 396-a (e.g., a nitride material), may be deposited above the conductors 395-a and over the liner material 375-b (e.g., to form a spacer), and may be etched to form dielectrics 396-a1 and 396-a2. Additionally, or alternatively, conductors 395-b1, 395-b2, and 395-b3 and conductors 395-c1, 395-c2, and 395-c3 may be deposited over the conductors 395-a1 through 395-a3 and the dielectrics 396-a1 and 396-a2 (e.g., after etching), and may be etched to expose an upper surface of the dielectrics 396. In some examples, the conductors 395-a, 395-b, and 395-c may be any combination of Poly-Si and metallic materials.

In some examples, one or more memory cells may be formed over the segments. For example, an electrode 397 may be formed above the exposed upper surfaces of the dielectrics 396-a and above the conductor 395-c1 to couple with the conductor 395-c1. A dielectric 396-b may be formed over the electrode 397 and may be etched to expose upper surfaces of the dielectrics 396 and conductors 395-c not in contact with the electrode 397 (e.g., conductors 395-c2 and 395-c3). An electrode 398 may be formed over the dielectric 396-b and at least a portion of the exposed surfaces of the dielectrics 396. In some examples, the electrode 397, the dielectric 396-b, and the electrode 398 may form a capacitor which may function as a memory cell to store charge, where the electrode 397 may be an example of a bottom electrode of the capacitor. In some examples, the conductors 395-a1, 395-b1, and 395-c1 may couple the electrode 397 of the capacitor with contacts 345 (and thereby with one or more digit lines 350) via one or more of the active portions 320-b1 in contact with the conductor 395-a1 (e.g., via one or more access devices for the memory cell including the capacitor).

FIG. 10 shows a block diagram 1000 of a manufacturing system 1020 that supports contact foot wet pullback with liner wet punch in accordance with examples as disclosed herein. The manufacturing system 1020 may be an example of aspects of a manufacturing system as described with reference to FIGS. 1 through 9. The manufacturing system 1020, or various components thereof, may be an example of means for performing various aspects of contact foot wet pullback with liner wet punch as described herein. For example, the manufacturing system 1020 may include an etching component 1025, a depositing component 1030, a bias component 1035, or any combination thereof. Each of these components may communicate, directly or indirectly, with one another (e.g., via one or more buses).

The etching component 1025 may be configured as or otherwise support a means for performing a first etching operation on a stack of materials and on a first insulative material formed on a substrate, the stack of materials including a first conductive material, a second conductive material, and a second insulative material, where the first etching operation forms a plurality of segments and exposes at least a portion of the first insulative material and at least a portion of the first conductive material, and where the first conductive material is a metallic material and forms a plurality of contacts extending at least partially through the first insulative material and coupling the second conductive material with active portions of the substrate. The depositing component 1030 may be configured as or otherwise support a means for depositing a first liner material over each exposed surface of the plurality of segments and over each exposed surface of the first insulative material. The bias component 1035 may be configured as or otherwise support a means for performing a directional gas bias operation on the stack of materials, where at least a portion of the first liner material that is in contact with an extension of the first conductive material that extends horizontally from one or more contacts of the plurality of contacts is transformed by the directional gas bias operation into a second liner material. In some examples, the etching component 1025 may be configured as or otherwise support a means for performing a second etching operation based at least in part on performing the directional gas bias operation, where the second etching operation removes the second liner material to expose a surface of the extension of the first conductive material. In some examples, the etching component 1025 may be configured as or otherwise support a means for performing a third etching operation to remove at least a portion of the extension of the first conductive material based at least in part on performing the second etching operation to expose the surface of the extension of the first conductive material.

In some examples, to support performing the first etching operation, the etching component 1025 may be configured as or otherwise support a means for etching the stack of materials to form the plurality of segments and to expose at least the portion of the first insulative material and at least the portion of the first conductive material. In some examples, to support performing the first etching operation, the etching component 1025 may be configured as or otherwise support a means for stopping the etching based at least in part on a second active portion of the substrate extending through at least a portion of the first insulative material, where the extension of the first conductive material is formed based at least in part on stopping the etching.

In some examples, the etching component 1025 may be configured as or otherwise support a means for performing a fourth etching operation to remove the first liner material, where the fourth etching operation exposes at least a second portion of the first conductive material, and where the second etching operation exposes at least the portion of the first insulative material. In some examples, the depositing component 1030 may be configured as or otherwise support a means for depositing a third liner material over each exposed surface of the plurality of segments and over each exposed surface of the first insulative material.

In some examples, the depositing component 1030 may be configured as or otherwise support a means for depositing a third liner material over remaining portions of the first liner material, over each exposed surface of the plurality of segments, and over each exposed surface of the first insulative material, where the second etching operation exposes at least the portion of the first insulative material.

In some examples, to support transforming at least the portion of the first liner material that is in contact with the extension of the first conductive material into a second liner material, the bias component 1035 may be configured as or otherwise support a means for removing a quantity of Carbon from at least the portion of the first liner material to form the second liner material, the second liner material including an oxide, where the second etching operation removes the second liner material based at least in part on removing the quantity of Carbon.

In some examples, the directional gas bias operation includes an oxygen plasma application operation. In some examples, the second etching operation includes a wet etching operation. In some examples, the third etching operation includes a cyclic high temperature wet etching operation. In some examples, the metallic material of the first conductive material includes a metal nitride material. In some examples, the second conductive material includes a metallic conductor material. In some examples, each segment includes an access line (e.g., a digit line) formed from the metallic conductor material.

FIG. 11 shows a flowchart illustrating a method 1100 that supports contact foot wet pullback with liner wet punch in accordance with examples as disclosed herein. The operations of method 1100 may be implemented by a manufacturing system or its components as described herein. For example, the operations of method 1100 may be performed by a manufacturing system as described with reference to FIGS. 1 through 10. In some examples, a manufacturing system may execute a set of instructions to control the functional elements of the device to perform the described functions. Additionally, or alternatively, the wireless manufacturing system may perform aspects of the described functions using special-purpose hardware.

At 1105, the method may include performing a first etching operation on a stack of materials and on a first insulative material formed on a substrate, the stack of materials including a first conductive material, a second conductive material, and a second insulative material, where the first etching operation forms a plurality of segments and exposes at least a portion of the first insulative material and at least a portion of the first conductive material, and where the first conductive material is a metallic material and forms a plurality of contacts extending at least partially through the first insulative material and coupling the second conductive material with active portions of the substrate. The operations of 1105 may be performed in accordance with examples as disclosed herein. In some examples, aspects of the operations of 1105 may be performed by an etching component 1025 as described with reference to FIG. 10.

At 1110, the method may include depositing a first liner material over each exposed surface of the plurality of segments and over each exposed surface of the first insulative material. The operations of 1110 may be performed in accordance with examples as disclosed herein. In some examples, aspects of the operations of 1110 may be performed by a depositing component 1030 as described with reference to FIG. 10.

At 1115, the method may include performing a directional gas bias operation on the stack of materials, where at least a portion of the first liner material that is in contact with an extension of the first conductive material that extends horizontally from one or more contacts of the plurality of contacts is transformed by the directional gas bias operation into a second liner material. The operations of 1115 may be performed in accordance with examples as disclosed herein. In some examples, aspects of the operations of 1115 may be performed by a bias component 1035 as described with reference to FIG. 10.

At 1120, the method may include performing a second etching operation based at least in part on performing the directional gas bias operation, where the second etching operation removes the second liner material to expose a surface of the extension of the first conductive material. The operations of 1120 may be performed in accordance with examples as disclosed herein. In some examples, aspects of the operations of 1120 may be performed by an etching component 1025 as described with reference to FIG. 10.

At 1125, the method may include performing a third etching operation to remove at least a portion of the extension of the first conductive material based at least in part on performing the second etching operation to expose the surface of the extension of the first conductive material. The operations of 1125 may be performed in accordance with examples as disclosed herein. In some examples, aspects of the operations of 1125 may be performed by an etching component 1025 as described with reference to FIG. 10.

In some examples, an apparatus as described herein may perform a method or methods, such as the method 1100. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing a first etching operation on a stack of materials and on a first insulative material formed on a substrate, the stack of materials including a first conductive material, a second conductive material, and a second insulative material, where the first etching operation forms a plurality of segments and exposes at least a portion of the first insulative material and at least a portion of the first conductive material, and where the first conductive material is a metallic material and forms a plurality of contacts extending at least partially through the first insulative material and coupling the second conductive material with active portions of the substrate; depositing a first liner material over each exposed surface of the plurality of segments and over each exposed surface of the first insulative material; performing a directional gas bias operation on the stack of materials, where at least a portion of the first liner material that is in contact with an extension of the first conductive material that extends horizontally from one or more contacts of the plurality of contacts is transformed by the directional gas bias operation into a second liner material; performing a second etching operation based at least in part on performing the directional gas bias operation, where the second etching operation removes the second liner material to expose a surface of the extension of the first conductive material; and performing a third etching operation to remove at least a portion of the extension of the first conductive material based at least in part on performing the second etching operation to expose the surface of the extension of the first conductive material.

Aspect 2: The method, apparatus, or non-transitory computer-readable medium of aspect 1, where performing the first etching operation includes operations, features, circuitry, logic, means, or instructions, or any combination thereof for etching the stack of materials to form the plurality of segments and to expose at least the portion of the first insulative material and at least the portion of the first conductive material and stopping the etching based at least in part on a second active portion of the substrate extending through at least a portion of the first insulative material, where the extension of the first conductive material is formed based at least in part on stopping the etching.

Aspect 3: The method, apparatus, or non-transitory computer-readable medium of any of aspects 1 through 2, further including operations, features, circuitry, logic, means, or instructions, or any combination thereof for performing a fourth etching operation to remove the first liner material, where the fourth etching operation exposes at least a second portion of the first conductive material, and where the second etching operation exposes at least the portion of the first insulative material and depositing a third liner material over each exposed surface of the plurality of segments and over each exposed surface of the first insulative material.

Aspect 4: The method, apparatus, or non-transitory computer-readable medium of any of aspects 1 through 3, further including operations, features, circuitry, logic, means, or instructions, or any combination thereof for depositing a third liner material over remaining portions of the first liner material, over each exposed surface of the plurality of segments, and over each exposed surface of the first insulative material, where the second etching operation exposes at least the portion of the first insulative material.

Aspect 5: The method, apparatus, or non-transitory computer-readable medium of any of aspects 1 through 4, where transforming at least the portion of the first liner material that is in contact with the extension of the first conductive material into a second liner material includes operations, features, circuitry, logic, means, or instructions, or any combination thereof for removing a quantity of Carbon from at least the portion of the first liner material to form the second liner material, the second liner material including an oxide, where the second etching operation removes the second liner material based at least in part on removing the quantity of Carbon.

Aspect 6: The method, apparatus, or non-transitory computer-readable medium of any of aspects 1 through 5, where the directional gas bias operation includes an oxygen plasma application operation.

Aspect 7: The method, apparatus, or non-transitory computer-readable medium of any of aspects 1 through 6, where the second etching operation includes a wet etching operation.

Aspect 8: The method, apparatus, or non-transitory computer-readable medium of any of aspects 1 through 7, where the third etching operation includes a cyclic high temperature wet etching operation.

Aspect 9: The method, apparatus, or non-transitory computer-readable medium of any of aspects 1 through 8, where the metallic material of the first conductive material includes a metal nitride material and the second conductive material includes a metallic conductor material, and where each segment includes an access line (e.g., a digit line) formed from the metallic conductor material.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: a substrate; a first insulative material in contact with the substrate; a segment of stacked materials, the segment of stacked materials including a first conductive material, a second conductive material, and a second insulative material, where the second conductive material and the second insulative material extend in a first horizontal direction, and where the first conductive material is a metallic material and includes a plurality of contacts aligned in the first horizontal direction, each of the plurality of contacts extending at least partially through the first insulative material and coupling the second conductive material with active portions of the substrate, where each contact of the plurality of contacts has a first dimension orthogonal to the first horizontal direction and to a vertical direction, the first dimension at a vertical location halfway between an upper edge of the first insulative material and a bottom edge of the contact, and where the each contact has a second dimension orthogonal to the first horizontal direction and to the vertical direction at a second vertical location of the upper edge of the first insulative material, where the second dimension is less than or equal to 20 percent larger than the first dimension; and one or more second active portions of the substrate extending through the first insulative material, where an upper edge of the one or more second active portions is at the second vertical location of the upper edge of the first insulative material and the second dimension of the plurality of contacts.

Aspect 11: The apparatus of aspect 10, where the second dimension is greater than or equal to 20 percent smaller than the first dimension.

Aspect 12: The apparatus of any of aspects 10 through 11, the apparatus further including: a liner material covering at least a portion of a surface of the first conductive material, the second conductive material, or the second insulative material of the segment of stacked materials, or any combination thereof, and covering at least a portion of a surface of the upper edge of the first insulative material and at least a portion of a surface of the upper edge of the one or more second active portions.

Aspect 13: The apparatus of aspect 12, the apparatus further including: a third conductive material above the first insulative material and in contact with at least a second active portion of the one or more second active portions of the substrate, where at least a portion of the liner material is between the third conductive material and the segment of stacked materials.

Aspect 14: The apparatus of any of aspects 12 through 13, where the liner material includes a silicon oxide material.

Aspect 15: The apparatus of any of aspects 10 through 14, the apparatus further including: a second segment of stacked materials, the second segment of stacked materials including a third insulative material, a fourth conductive material, and a fourth insulative material, where the fourth conductive material and the fourth insulative material extend in the first horizontal direction, and where the third insulative material is in contact with at least a portion of the first insulative material, where at least the portion of the first insulative material is between different second active portions of the one or more second active portions of the substrate.

Aspect 16: The apparatus of aspect 15, where the third insulative material includes two dielectric materials, the two dielectric materials including a first inter-layer dielectric material and a second inter-layer dielectric material different form the first inter-layer dielectric material, where both the first inter-layer dielectric material and the second inter-layer dielectric material are different from a third inter-layer dielectric material of the first insulative material.

Aspect 17: The apparatus of any of aspects 10 through 16, where the metallic material of the first conductive material includes a metal nitride material, and the second conductive material includes a metallic conductor material.

Aspect 18: The apparatus of any of aspects 10 through 17, where the first insulative material includes an inter-layer dielectric material, and the second insulative material includes a nitride material.

An apparatus is described. The following provides an overview of aspects of the apparatus as described herein:

Aspect 19: An apparatus, including: a substrate; a first insulative material in contact with the substrate; and a first segment of stacked materials, the first segment of stacked materials including a first conductive material, a second conductive material, and a second insulative material, where the second conductive material and the second insulative material extend in a first horizontal direction, and where the first conductive material is a metallic material and includes a plurality of contacts extending at least partially through the first insulative material and coupling the first conductive material with active portions of the substrate, where formation of the plurality of contacts of the first conductive material includes: depositing a first liner material over each exposed surface of the first segment of stacked materials; performing a directional gas bias operation on the first segment of stacked materials, where at least a portion of the first liner material that is in contact with an extension of the first conductive material that extends horizontally from one or more contacts of the plurality of contacts is transformed by the directional gas bias operation into a second liner material; performing a first etching operation based at least in part on performing the directional gas bias operation, where the first etching operation removes the second liner material to expose a surface of the extension of the first conductive material; and performing a second etching operation to remove at least a portion of the extension of the first conductive material based at least in part on performing the first etching operation to expose the surface of the extension of the first conductive material.

Aspect 20: The apparatus of aspect 19, where the formation of the plurality of contacts of the first conductive material further includes: etching a stack of materials to form the first segment of stacked materials and to expose at least the portion of the first insulative material and at least the portion of the first conductive material; and stopping the etching based at least in part on a second active portion of the substrate extending through at least a portion of the first insulative material, where the extension of the first conductive material is formed based at least in part on stopping the etching.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The article “a” as used in the claims shall be understood to refer to one or more than one of the specified components. Thus, the terms “a,” “at least one,” and “one or more” are to be construed to be interchangeable. Subsequent reference to a component introduced with the article “a” using the terms “the” or “said” shall be construed as referring to any or all of the one or more components. That is, a component introduced with the article “a” shall be understood to mean “one or more components,” and referring to “the component” subsequently in the claims shall be understood to be equivalent to referring to “the one or more components.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
performing a first etching operation on a stack of materials and on a first insulative material formed on a substrate, the stack of materials comprising a first conductive material, a second conductive material, and a second insulative material, wherein the first etching operation forms a plurality of segments and exposes at least a portion of the first insulative material and at least a portion of the first conductive material, and wherein the first conductive material is a metallic material and forms a plurality of contacts extending at least partially through the first insulative material and coupling the second conductive material with active portions of the substrate;
depositing a first liner material over each exposed surface of the plurality of segments and over each exposed surface of the first insulative material;
performing a directional gas bias operation on the stack of materials, wherein at least a portion of the first liner material that is in contact with an extension of the first conductive material that extends horizontally from one or more contacts of the plurality of contacts is transformed by the directional gas bias operation into a second liner material;
performing a second etching operation based at least in part on performing the directional gas bias operation, wherein the second etching operation removes the second liner material to expose a surface of the extension of the first conductive material; and
performing a third etching operation to remove at least a portion of the extension of the first conductive material based at least in part on performing the second etching operation to expose the surface of the extension of the first conductive material.

2. The method of claim 1, wherein performing the first etching operation comprises:
etching the stack of materials to form the plurality of segments and to expose at least the portion of the first insulative material and at least the portion of the first conductive material; and
stopping the etching based at least in part on a second active portion of the substrate extending through at least a portion of the first insulative material, wherein the extension of the first conductive material is formed based at least in part on stopping the etching.

3. The method of claim 1, further comprising:
performing a fourth etching operation to remove the first liner material, wherein the fourth etching operation exposes at least a second portion of the first conductive material, and wherein the second etching operation exposes at least the portion of the first insulative material; and
depositing a third liner material over each exposed surface of the plurality of segments and over each exposed surface of the first insulative material.

4. The method of claim 1, further comprising:
depositing a third liner material over remaining portions of the first liner material, over each exposed surface of the plurality of segments, and over each exposed surface of the first insulative material, wherein the second etching operation exposes at least the portion of the first insulative material.

5. The method of claim 1, wherein transforming at least the portion of the first liner material that is in contact with the extension of the first conductive material into a second liner material comprises:
removing a quantity of Carbon from at least the portion of the first liner material to form the second liner material, the second liner material comprising an oxide, wherein the second etching operation removes the second liner material based at least in part on removing the quantity of Carbon.

6. The method of claim 1, wherein the directional gas bias operation comprises an oxygen plasma application operation.

7. The method of claim 1, wherein the second etching operation comprises a wet etching operation.

8. The method of claim 1, wherein the third etching operation comprises a cyclic high temperature wet etching operation.

9. The method of claim 1, wherein the metallic material of the first conductive material comprises a metal nitride material, and wherein the second conductive material comprises a metallic conductor material, and wherein each segment comprises an access line formed from the metallic conductor material.

10. An apparatus, comprising:
a substrate;
a first insulative material in contact with the substrate;
a segment of stacked materials, the segment of stacked materials comprising a first conductive material, a second conductive material, and a second insulative material, wherein the second conductive material and the second insulative material extend in a first horizontal direction, and wherein the first conductive material is a metallic material and comprises a plurality of contacts aligned in the first horizontal direction, each of the plurality of contacts extending at least partially through the first insulative material and coupling the second conductive material with active portions of the substrate, wherein each contact of the plurality of contacts has a first dimension orthogonal to the first horizontal direction and to a vertical direction, the first dimension at a vertical location halfway between an upper edge of the first insulative material and a bottom edge of the contact, and wherein the each contact has a second dimension orthogonal to the first horizontal direction and to the vertical direction at a second vertical location of the upper edge of the first insulative material, wherein the second dimension is less than or equal to 20 percent larger than the first dimension; and
one or more second active portions of the substrate extending through the first insulative material, wherein an upper edge of the one or more second active portions is at the second vertical location of the upper edge of the first insulative material and the second dimension of the plurality of contacts.

11. The apparatus of claim 10, wherein the second dimension is greater than or equal to 20 percent smaller than the first dimension.

12. The apparatus of claim 10, the apparatus further comprising:
a liner material covering at least a portion of a surface of the first conductive material, the second conductive material, or the second insulative material of the segment of stacked materials, or any combination thereof, and covering at least a portion of a surface of the upper edge of the first insulative material and at least a portion of a surface of the upper edge of the one or more second active portions.

13. The apparatus of claim 12, the apparatus further comprising:
a third conductive material above the first insulative material and in contact with at least a second active portion of the one or more second active portions of the substrate, wherein at least a portion of the liner material is between the third conductive material and the segment of stacked materials.

14. The apparatus of claim 12, wherein the liner material comprises a silicon oxide material.

15. The apparatus of claim 10, the apparatus further comprising:
a second segment of stacked materials, the second segment of stacked materials comprising a third insulative material, a fourth conductive material, and a fourth insulative material, wherein the fourth conductive material and the fourth insulative material extend in the first horizontal direction, and wherein the third insulative material is in contact with at least a portion of the first insulative material, wherein at least the portion of the first insulative material is between different second active portions of the one or more second active portions of the substrate.

16. The apparatus of claim 15, wherein the third insulative material comprises two dielectric materials, the two dielectric materials comprising a first inter-layer dielectric material and a second inter-layer dielectric material different form the first inter-layer dielectric material, wherein both the first inter-layer dielectric material and the second inter-layer dielectric material are different from a third inter-layer dielectric material of the first insulative material.

17. The apparatus of claim 10, wherein the metallic material of the first conductive material comprises a metal nitride material, and wherein the second conductive material comprises a metallic conductor material.

18. The apparatus of claim 10, wherein the first insulative material comprises an inter-layer dielectric material, and wherein the second insulative material comprises a nitride material.

19. An apparatus, comprising:
a substrate;
a first insulative material in contact with the substrate; and
a first segment of stacked materials, the first segment of stacked materials comprising a first conductive material, a second conductive material, and a second insulative material, wherein the second conductive material and the second insulative material extend in a first horizontal direction, and wherein the first conductive material is a metallic material and comprises a plurality of contacts extending at least partially through the first insulative material and coupling the first conductive material with active portions of the substrate, wherein formation of the plurality of contacts of the first conductive material comprises:
depositing a first liner material over each exposed surface of the first segment of stacked materials;
performing a directional gas bias operation on the first segment of stacked materials, wherein at least a portion of the first liner material that is in contact with an extension of the first conductive material that extends horizontally from one or more contacts of the plurality of contacts is transformed by the directional gas bias operation into a second liner material;
performing a first etching operation based at least in part on performing the directional gas bias operation, wherein the first etching operation removes the second liner material to expose a surface of the extension of the first conductive material; and
performing a second etching operation to remove at least a portion of the extension of the first conductive material based at least in part on performing the first etching operation to expose the surface of the extension of the first conductive material.

20. The apparatus of claim 19, wherein the formation of the plurality of contacts of the first conductive material further comprises:
etching a stack of materials to form the first segment of stacked materials and to expose at least the portion of the first insulative material and at least the portion of the first conductive material; and
stopping the etching based at least in part on a second active portion of the substrate extending through at least a portion of the first insulative material, wherein the extension of the first conductive material is formed based at least in part on stopping the etching.
